(19) United States
(12) Patent Application Publication
(10) Pub. No.: US 2026/0164939 A1
(43) Pub. Date: Jun. 11, 2026

(54) DISPLAY DEVICE, METHOD OF MANUFACTURING THE SAME, AND ELECTRONIC DEVICE

(71) Applicant: Samsung Display Co., Ltd., Yongin-si (KR)

(72) Inventors: Su Bin BAE, Yongin-si (KR); Bong Kyun KIM, Yongin-si (KR); Hyo Min KO, Yongin-si (KR); Gun Shik KIM, Yongin-si (KR)

(21) Appl. No.: 19/181,030

(22) Filed: Apr. 16, 2025

(30) Foreign Application Priority Data
Jun. 21, 2024 (KR) 10-2024-0081240
Jul. 31, 2024 (KR) 10-2024-0101830

(51) Int. Cl. H10K 59/122; H10K 59/12; H10K 59/35

(52) U.S. Cl. CPC H10K 59/122; H10K 59/1201; H10K 59/353

(57) ABSTRACT

A display device includes: a via layer on a pixel circuit layer; anodes spaced from each other on the via layer; a pixel-defining layer on the via layer and on edges of the anodes; and trenches corresponding to the anodes, respectively, and spaced from each other, each of the trenches penetrating a portion of the via layer and the pixel-defining layer. Aspect ratios of the trenches are greater than 4.

### CROSS-REFERENCE TO RELATED APPLICATION

The present application claims priority to and the benefit of Korean Patent Application No. 10-2024-0081240, filed on Jun. 21, 2024, and Korean Patent Application No. 10-2024-0101830, filed on Jul. 31, 2024, in the Korean Intellectual Property Office, the entire disclosures of all of which are incorporated by reference herein.

### BACKGROUND

### 1. Field

Aspects of some embodiments of the present disclosure relate to a display device, a method of manufacturing the display device, and an electronic device.

### 2. Description of the Related Art

With the development of information technologies, the importance of a display device, which is a connection medium between a user and information, has increased. Accordingly, various display devices, such as a liquid crystal display device and an organic light-emitting display device, are increasingly being used.

The above information disclosed in this Background section is for enhancement of understanding of the background of the present disclosure, and therefore, it may contain information that does not constitute prior art.

### SUMMARY

Some embodiments of the present disclosure may be directed to a display device in which a leakage current between sub-pixels may be reduced (or eliminated), a method of manufacturing the display device, and an electronic device including the display device.

According to one or more embodiments of the present disclosure, a display device includes: a via layer on a pixel circuit layer; anodes spaced from each other on the via layer; a pixel-defining layer on the via layer and on edges of the anodes; and trenches corresponding to the anodes, respectively, and spaced from each other, each of the trenches penetrating a portion of the via layer and the pixel-defining layer. Aspect ratios of the trenches are greater than 4.

In some embodiments, the trenches may have a tapered shape having a width that increases in a thickness direction.

In some embodiments, a width of a top surface of each of the trenches may be 80 nm to 130 nm.

In some embodiments, thicknesses of the trenches may be about 600 nm or more.

In some embodiments, taper angles of the trenches may be about 85 degrees or more and less than about 90 degrees.

In some embodiments, the pixel-defining layer may include a triple-layered structure.

In some embodiments, the triple-layered structure of the pixel-defining layer may include: a first layer including silicon oxide; a second layer on the first layer, and including silicon nitride; and a third layer on the second layer, and including silicon oxide.

In some embodiments, the second layer and the third layer may form an undercut structure by the trenches.

In some embodiments, the trenches may surround around the anodes, respectively.

In some embodiments, the display device may further include: a light-emitting structure on the anodes and the pixel-defining layer; a cathode on the light-emitting structure; a capping layer on the cathode; and an encapsulation layer on the capping layer.

In some embodiments, the light-emitting structure may include: a p-type hole injection layer; a first light-emitting structure on the p-type hole injection layer; a first charge generation layer on the first light-emitting structure; a second light-emitting structure on the first charge generation layer; a second charge generation layer on the second light-emitting structure; and a third light-emitting structure on the second charge generation layer.

In some embodiments, the first light-emitting structure may include: a first hole transport layer; a first light-emitting layer on the first hole transport layer, and configured to emit light of a red color; and a first electron transport layer on the first light-emitting layer. The second light-emitting structure may include: a second hole transport layer; a second light-emitting layer on the second hole transport layer, and configured to emit light of a blue color; and a second electron transport layer on the second light-emitting layer. The third light-emitting structure may include: a third hole transport layer; a third light-emitting layer on the third hole transport layer, and configured to emit light of a green color; and a third electron transport layer on the third light-emitting layer.

In some embodiments, the p-type hole injection layer may have a discontinuous structure by the trenches, and the first charge generation layer and the second charge generation layer may have a discontinuous structure by voids respectively corresponding to the trenches.

According to one or more embodiments of the present disclosure, a method of manufacturing a display device includes: forming a via layer on a pixel circuit layer; forming anodes spaced from each other on the via layer; forming a pixel-defining layer on the via layer and on edges of the anodes; and forming trenches surrounding around the anodes, respectively, the trenches being spaced from each other by etching portions of the via layer and the pixel-defining layer. Aspect ratios of the trenches are greater than 4.

In some embodiments, the trenches may have a tapered shape having a width that increases in a thickness direction.

In some embodiments, a width of a top surface of each of the trenches may be 80 nm to 130 nm.

In some embodiments, thicknesses of the trenches may be about 600 nm or more.

In some embodiments, taper angles of the trenches may be about 85 degrees or more and less than about 90 degrees.

In some embodiments, the pixel-defining layer may include: a first layer including silicon oxide; a second layer on the first layer, and including silicon nitride; and a third layer on the second layer, and including silicon oxide. The second layer and the third layer may form an undercut structure by the trenches.

According to one or more embodiments of the present disclosure, an electronic device includes: a display panel; a processor configured to drive the display panel; and a voltage generating circuit configured to supply a voltage of a driving power source to the display panel. The display panel includes: a via layer on a pixel circuit layer; anodes spaced from each other on the via layer; a pixel-defining layer on the via layer and on edges of the anodes; and trenches corresponding to the anodes, respectively, and spaced from each other, each of the trenches penetrating a portion of the via layer and the pixel-defining layer. Aspect ratios of the trenches are greater than 4.

In some embodiments, the trenches may have a tapered shape having a width that increases in a thickness direction.

In some embodiments, a width of a top surface of each of the trenches may be 80 nm to 130 nm, thicknesses of the trenches may be about 600 nm or more, and taper angles of the trenches may be about 85 degrees or more and less than about 90 degrees.

In some embodiments, the pixel-defining layer may include a triple-layered structure.

In some embodiments, the triple-layered structure of the pixel-defining layer may include: a first layer including silicon oxide; a second layer on the first layer, and including silicon nitride; and a third layer on the second layer, and including silicon oxide.

In some embodiments, the second layer and the third layer may form an undercut structure by the trenches.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a block diagram of a display device in accordance with an embodiment of the present disclosure.

FIG. 2 is a block diagram of a sub-pixel in accordance with an embodiment of the present disclosure.

FIG. 3 is a plan view of a display panel in accordance with an embodiment of the present disclosure.

FIG. 4 is a plan view of a pixel in accordance with an embodiment of the present disclosure.

FIG. 5 is a plan view of a pixel in accordance with an embodiment of the present disclosure.

FIG. 6 is a plan view of a pixel in accordance with an embodiment of the present disclosure.

FIG. 7 is a sectional view taken along the line I-I′ of FIG. 4 in accordance with an embodiment of the present disclosure.

FIG. 8 is a plan view of anodes and trenches in accordance with an embodiment of the present disclosure.

FIG. 9 is a sectional view taken along the line I-I′ of FIG. 4 in accordance with an embodiment of the present disclosure.

FIG. 10 is a sectional view of a light-emitting structure in accordance with an embodiment of the present disclosure.

FIG. 11 is a sectional view taken along the line I-I′ of FIG. 4 in accordance with an embodiment of the present disclosure.

FIG. 12 is a block diagram of a display system in accordance with an embodiment of the present disclosure.

FIG. 13 is a perspective view of a head-mounted display device in accordance with an embodiment of the present disclosure.

FIG. 14 is a view illustrating the head-mounted display device shown in FIG. 13 that is worn by a user in accordance with an embodiment of the present disclosure.

FIG. 15 is a block diagram of an electronic device in accordance with an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

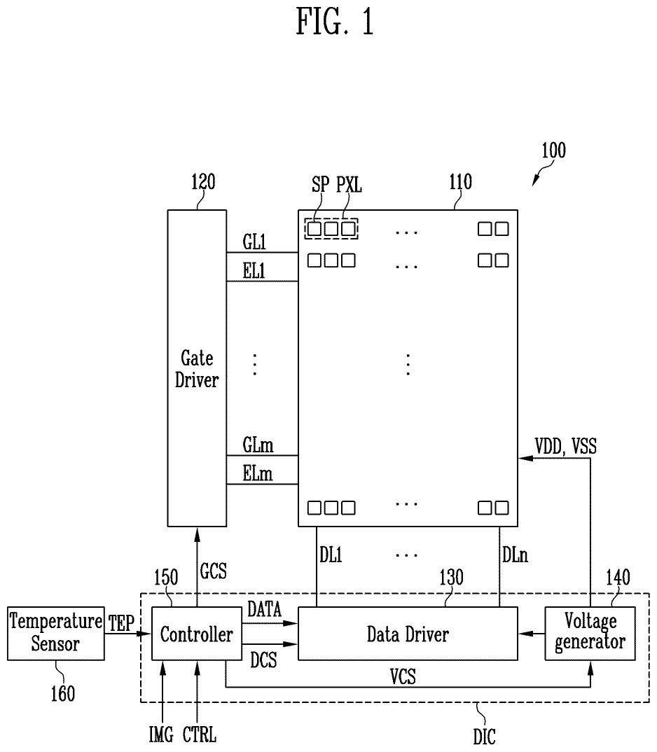

FIG. 1 is a block diagram of a display device in accordance with an embodiment of the present disclosure.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to mth gate lines GL1 to GLm, where m is a positive integer. The sub-pixels SP may be connected to the data driver 130 through first to nth data lines DL1 to DLn, where n is a positive integer.

Each of the sub-pixels SP may include at least one light-emitting element to generate light. Accordingly, each of the sub-pixels SP may generate light of a desired color (e.g., a specific or predetermined color), such as red, green, blue, cyan, magenta, or yellow. Two or more sub-pixels SP from among the sub-pixels SP may constitute one pixel PXL. For example, three sub-pixels SP may constitute one pixel PXL as shown in FIG. 1, but the present disclosure is not limited thereto.

The gate driver 120 may be connected to the sub-pixels SP arranged along a row direction through the first to mth gate lines GL1 to GLm. The gate driver 120 may output gate signals to the first to mth gate lines GL1 to GLm in response to a gate control signal GCS. The gate control signal GCS may include a start signal indicating a start of each frame, a horizontal synchronization signal for outputting gate signals in synchronization with timings at which data signals are applied, and the like.

First to mth emission control lines EL1 to ELm connected to the sub-pixels SP in the row direction may be further provided. The gate driver 120 may include an emission control driver to control the first to mth emission control lines EL1 to ELm, and the emission control driver may operate under the control of the controller 150.

The gate driver 120 may be disposed at one side of the display panel 110. However, the present disclosure is not limited thereto. For example, the gate driver 120 may be divided into two or more drivers that are physically and/or logically divided, and these drivers may be disposed at one side of the display panel 110 and another side (e.g., an opposite side) of the display panel 110, which is opposite to the one side. As such, in accordance with some embodiments, the gate driver 120 may be disposed in various suitable forms at the periphery of the display panel 110.

The data driver 130 may be connected to the sub-pixels SP arranged along a column direction through the first to nth data lines DL1 to DLn. The data driver 130 may receive image data DATA and a data control signal DCS from the controller 150. The data driver 130 may operate in response to the data control signal DCS. The data control signal DCS may include a source start pulse, a source shift clock, a source output enable signal, and the like.

The data driver 130 may apply data signals having grayscale voltages corresponding to the image data DATA to the first to nth data lines DL1 to DLn by using voltages from the voltage generator 140. When a gate signal is applied to each of the first to mth gate lines GL1 to GLm, data signals corresponding to the image data DATA may be applied to the first to nth data lines DL1 to DLn. Accordingly, corresponding sub-pixels SP may generate light corresponding to the data signals. As such, an image may be displayed on the display panel 110.

The gate driver 120 and the data driver 130 may include complementary metal-oxide semiconductor (CMOS) circuit elements.

The voltage generator 140 may operate in response to a voltage control signal VCS from the controller 150. The voltage generator 140 may generate a 1 plurality of voltages, and may provide the generated voltages to the components of the display device 100. For example, the voltage generator 140 may generate a plurality of voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively higher voltage level, and the second power voltage VSS may have a voltage level lower than the voltage level of the first power voltage VDD. However, the present disclosure is not limited thereto. For example, the first power voltage VDD or the second power voltage VSS may be provided by an external device of the display device 100.

The voltage generator 140 may generate various suitable voltages. For example, the voltage generator 140 may generate an initialization voltage applied to the sub-pixels SP. For example, a reference voltage (e.g., a predetermined reference voltage) may be applied to the first to nth data lines DL1 to DLn in a sensing operation for sensing electrical characteristics of transistors and/or light-emitting elements of the sub-pixels SP, and the voltage generator 140 may generate the reference voltage.

The controller 150 may control the overall operations of the display device 100. The controller 150 may receive, from the outside, input image data IMG and a control signal CTRL for controlling a display thereof. The controller 150 may provide the gate control signal GCS, the data control signal DCS, and the voltage control signal VCS in response to the control signal CTRL.

The controller 150 may convert the input image data IMG to be suitable for the display device 100 or the display panel 110, thereby outputting the image data DATA. The controller 150 may align the input image data IMG to be suitable for the sub-pixels SP in units of rows, thereby outputting the image data DATA.

Two or more components from among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components that are functionally divided in one driver integrated circuit DIC. However, the present disclosure is not limited thereto. For example, at least one of the data driver 130, the voltage generator 140, and the controller 150 may be provided as a component distinguished from the driver integrated circuit DIC.

The display device 100 may include at least one temperature sensor 160. The temperature sensor 160 may sense a temperature at the periphery thereof, and generate temperature data TEP indicating the sensed temperature. The temperature sensor 160 may be disposed to be adjacent to the display panel 110 and/or the driver integrated circuit DIC.

The controller 150 may control various operations of the display device 100 in response to the temperature data TEP. The controller 150 may adjust the luminance of an image output from the display panel 110 in response to the temperature data TEP. For example, the controller 150 may control the components such as the data driver 130 and/or the voltage generator 140, thereby adjusting data signals and the first and second power voltages VDD and VSS.

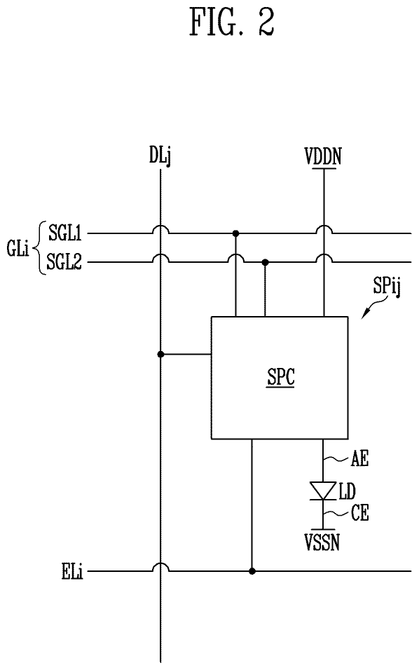

FIG. 2 is a block diagram of a sub-pixel in accordance with an embodiment of the present disclosure.

In FIG. 2, a sub-pixel SPij arranged on an ith row (where i is an integer greater than or equal to 1 and smaller than or equal to m) and a jth column (where j is an integer greater than or equal to 1 and smaller than or equal to n) from among the sub-pixels SP described above with reference to FIG. 1 is illustrated as a representative example.

Referring to FIG. 2, the sub-pixel SPij may include a sub-pixel circuit SPC and a light-emitting element LD.

The light-emitting element LD may be connected between a first power voltage node VDDN and a second power voltage node VSSN. The first power voltage node VDDN may be a node for transferring the first power voltage VDD described above with reference to FIG. 1, and the second power voltage node VSSN may be a node transferring the second power voltage VSS.

An anode AE of the light-emitting element LD may be connected to the first power voltage node VDDN through the sub-pixel circuit SPC, and a cathode CE of the light-emitting element LD may be connected to the second power voltage node VSSN. For example, the anode AE of the light-emitting element LD may be connected to the first power voltage node VDDN through one or more transistors included in the sub-pixel circuit SPC.

The sub-pixel circuit SPC may be connected to an ith gate line GLi from among the first to mth gate lines GL1 to GLm described above with reference to FIG. 1, an ith emission control line ELi from among the first to mth emission control lines EL1 to ELm, and a jth data line DLj from among the first to nth data lines DL1 to DLn, which may be referred to as signal lines. The sub-pixel circuit SPC may control the light-emitting element LD according to signals received through the signal lines.

The sub-pixel circuit SPC may operate in response to a gate signal received through the ith gate line GLi. The ith gate line GLi may include one or more sub-gate lines. As shown in FIG. 2, the ith gate line GLi may include first and second sub-gate lines SGL1 and SGL2. The sub-pixel circuit SPC may operate in response to gate signals received through the first and second sub-gate lines SGL1 and SGL2. As such, when the ith gate line GLi includes two or more sub-gate lines, the sub-pixel circuit SPC may operate in response to gate signals receiving through the two or more sub-gate lines.

The sub-pixel circuit SPC may operate in response to an emission control signal received through the ith emission control line ELi. The ith emission control line ELi may include one or more sub-emission control lines. When the ith emission control line ELi includes two or more sub-emission control lines, the sub-pixel circuit SPC may operate in response to emission control signals receives through the two or more emission control lines.

The sub-pixel circuit SPC may receive a data signal through the jth data line DLj. The sub-pixel circuit SPC may store a voltage corresponding to the data signal in response to at least one of the gate signals received through the first and/or second sub-gate lines SGL1 and/or SGL2. The sub-pixel circuit SPC may control a current flowing from the first power voltage node VDDN to the second power voltage node VSSN through the light-emitting element LD according to the stored voltage, in response to the emission control signal received through the ith emission control line ELi. Accordingly, the light-emitting element LD may generate light having a luminance corresponding to the data signal.

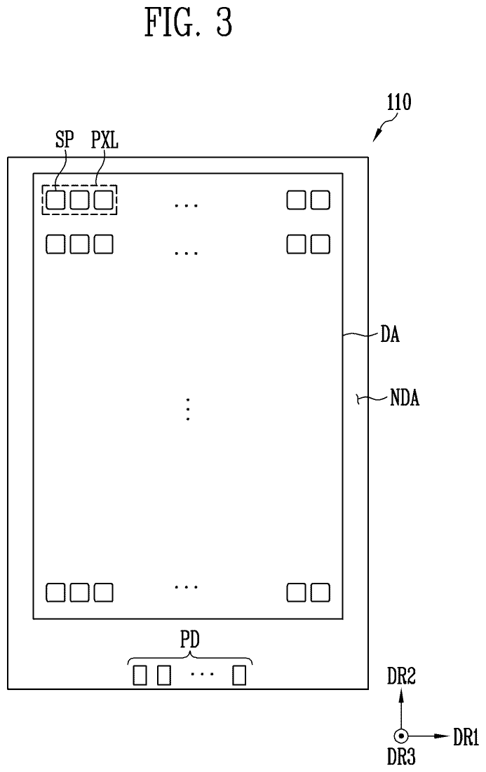

FIG. 3 is a plan view of a display panel in accordance with an embodiment of the present disclosure.

Referring to FIG. 3, the display panel 110 may include a display area DA and a non-display area NDA. The display panel 110 may display images through the display area DA. The non-display area NDA may be disposed at a periphery of the display area DA.

The display panel 110 may include sub-pixels SP and pads PD.

The sub-pixels SP may be disposed in the display area DA. The sub-pixels SP may be arranged in a matrix form along a first direction DR1 and a second direction DR2 crossing or intersecting the first direction DR1. However, the present disclosure is not limited thereto. For example, the sub-pixels SP may be arranged in a zigzag form along the first direction DR1 and the second direction DR2. For example, the sub-pixels SP may be disposed in a diamond form (e.g., a PENTILE® form, PENTILE® being a duly registered trademark of Samsung Display Co., Ltd.). The first direction DR1 may be a row direction, and the second direction DR2 may be a column direction.

Two or more sub-pixels SP from among the sub-pixels SP may constitute one pixel PXL.

A component for controlling the sub-pixels SP may be disposed in the non-display area NDA. For example, lines connected to the sub-pixels SP, such as the first to mth gate lines GL1 to GLm and the first to nth data lines DL1 to DLn described above with reference to FIG. 1, may be disposed in the non-display area NDA.

At least one of the gate driver 120, the data driver 130, the voltage generator 140, the controller 150, and the temperature sensor 160, which are described above with reference to FIG. 1, may be integrated in the non-display area NDA of the display panel 110. The gate driver 120 described above with reference to FIG. 1 may be mounted on the display panel 110, and may be disposed in the non-display area NDA. However, the present disclosure is not limited thereto. For example, the gate driver 120 may be implemented as an integrated circuit distinguished from the display panel 110. The temperature sensor 160 may be disposed in the non-display area NDA to sense a temperature of the display panel 110.

The pads PD may be disposed in the non-display area NDA. The pads PD may be electrically connected to the sub-pixels SP through the lines. For example, the pads PD may be connected to the sub-pixels SP through the first to nth data lines DL1 to DLn (e.g., see FIG. 1).

The pads PD may interface the display panel 110 with other components of the display device 100 (e.g., see FIG. 1). Voltages and signals, which are used for the operations of the components included in the display panel 110, may be provided from the driver integrated circuit DIC described above with reference to FIG. 1 through the pads PD. For example, the first to nth data lines DL1 to DLn may be connected to the driver integrated circuit DIC through the pads PD. For example, the first and second power voltages VDD and VSS may be received from the driver integrated circuit DIC through the pads PD. When the gate driver 120 is mounted in the display panel 110, the gate control signal GCS may be transmitted from the driver integrated circuit DIC to the gate driver 120 through the pads PD.

A circuit board may be electrically connected to the pads PD using a conductive adhesive member, such as an anisotropic conductive film. The circuit board may be a Flexible Printed Circuit Board (FPCB) or a flexible film, which includes a flexible material. The driver integrated circuit DIC may be mounted on the circuit board to be electrically connected to the pads PD.

The display area DA may have various suitable shapes. The display area DA may have a closed-loop shape including linear sides and/or curved sides. For example, the display area DA may have various suitable shapes, such as a polygon, a circle, a semicircle, and/or an ellipse.

The display panel 110 may have a flat or substantially flat display surface. However, the present disclosure is not limited thereto. For example, the display panel 110 may have at least a partially rounded display surface. The display panel 110 may be bendable, foldable, or rollable. The display panel 110 and/or the substrate SUB may include suitable materials having a flexibility.

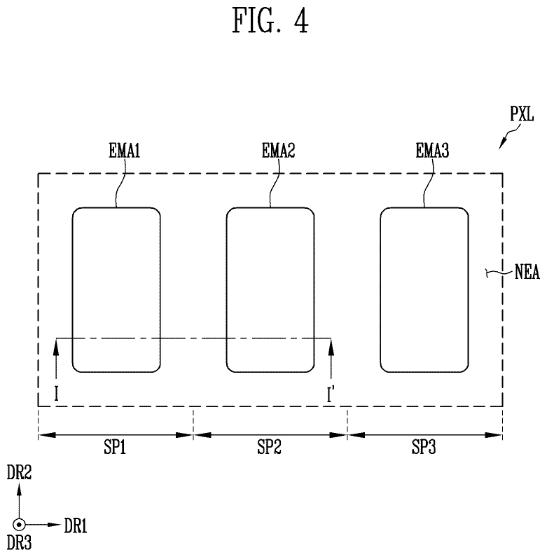

FIG. 4 is a plan view of a pixel in accordance with an embodiment of the present disclosure.

Referring to FIG. 4, the pixel PXL may include first to third sub-pixels SP1 to SP3 arranged along the first direction DR1.

The first sub-pixel SP1 may include a first emission area EMA1, and a non-emission area NEA at the periphery of the first emission area EMA1. The second sub-pixel SP2 may include a second emission area EMA2, and the non-emission area NEA at the periphery of the second emission area EMA2. The third sub-pixel SP3 may include a third emission area EMA3, and the non-emission area NEA at the periphery of the third emission area EMA3.

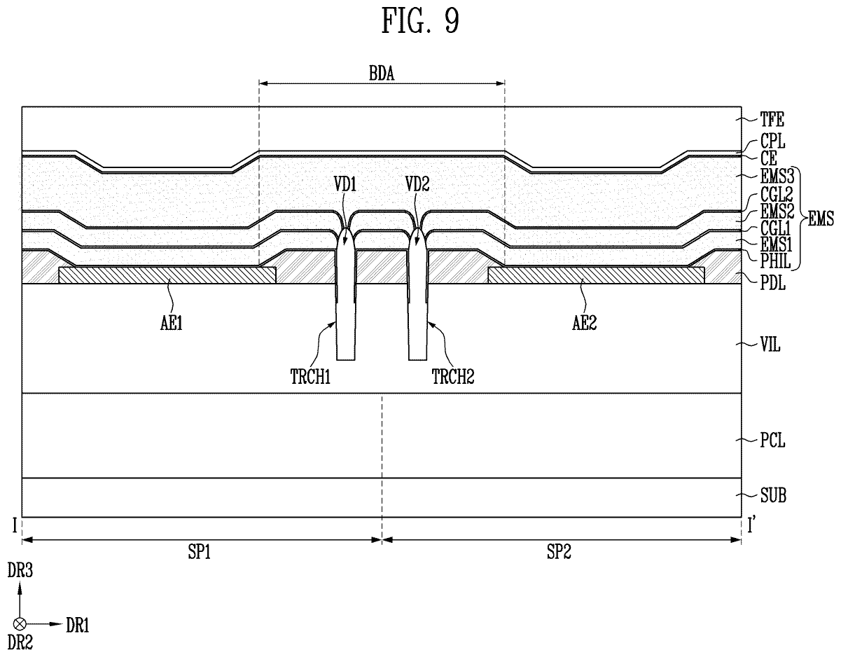

The first emission area EMA1 may be an area in which light is emitted from a portion of a light-emitting structure EMS (e.g., see FIG. 9), which corresponds to the first sub-pixel SP1. The second emission area EMA2 may be an area in which light is emitted from a portion of the light-emitting structure EMS, which corresponds to the second sub-pixel SP2. The third emission area EMA3 may be an area in which light is emitted from a portion of the light-emitting structure EMS, which corresponds to the third sub-pixel SP3.

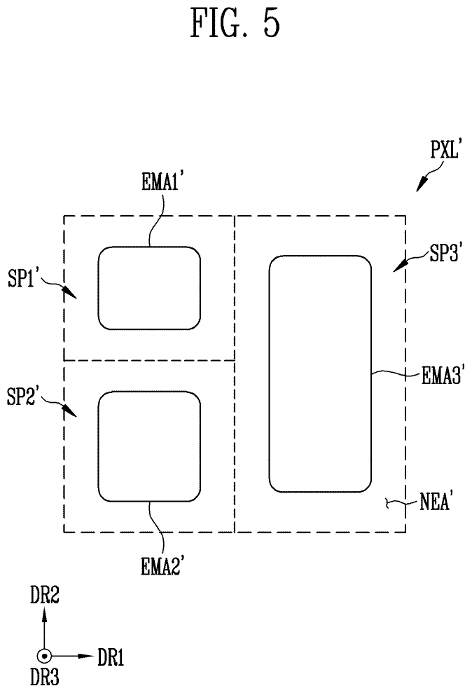

FIG. 5 is a plan view of a pixel in accordance with an embodiment of the present disclosure.

Referring to FIG. 5, a pixel PXL′ may include first to third sub-pixels SP1′ to SP3′.

The first sub-pixel SP1′ may include a first emission area EMA1′, and a non-emission area NEA′ at the periphery of the first emission area EMA1′. The second sub-pixel SP2′ may include a second emission area EMA2′, and the non-emission area NEA′ at the periphery of the second emission area EMA2′. The third sub-pixel SP3′ may include a third emission area EMA3′, and the non-emission area NEA′ at the periphery of the third emission area EMA3′.

The first sub-pixel SP1′ and the second sub-pixel SP2′ may be arranged along the second direction DR2. The third sub-pixel SP3′ may be disposed in the first direction DR1 with respect to each of the first and second sub-pixels SP1′ and SP2′.

The second sub-pixel SP2′ may have an area greater than an area of the first sub-pixel SP1′, and the third sub-pixel SP3′ may have an area greater than the area of the second sub-pixel SP2′. Accordingly, the second emission area EMA2′ may have an area greater than an area of the first emission area EMA1′, and the third emission area EMA3′ may have an area greater than the area of the second emission area EMA2′. However, the present disclosure is not limited thereto. For example, the first and second sub-pixels SP1′ and SP2′ may have the same or substantially the same area as each other, and the third sub-pixel SP3′ may have an area greater than the area of each of the first and second sub-pixels SP1′ and SP2′. As such, the areas of the first to third sub-pixels SP1′ to SP3′ may be variously modified as needed or desired.

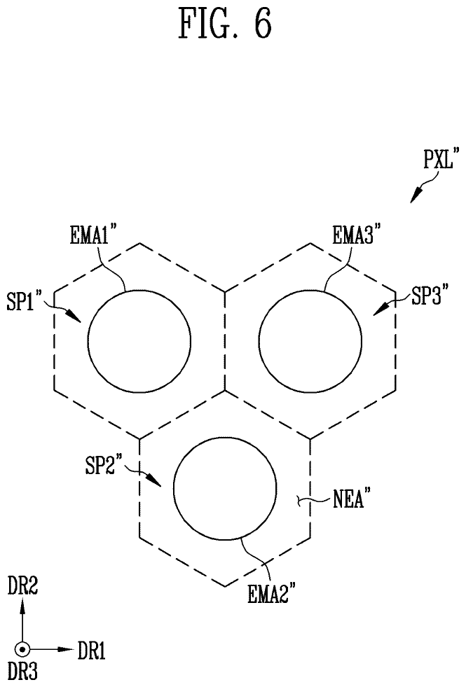

FIG. 6 is a plan view of a pixel in accordance with an embodiment of the present disclosure.

Referring to FIG. 6, a pixel PXL″ may include first to third sub-pixels SP1″ to SP3″.

The first sub-pixel SP1″ may include a first emission area EMA1″, and a non-emission area NEA″ at the periphery of the first emission area EMA1″. The second sub-pixel SP2″ may include a second emission area EMA2″, and the non-emission area NEA″ at the periphery of the second emission area EMA2″. The third sub-pixel SP3″ may include a third emission area EMA3″, and the non-emission area NEA″ at the periphery of the third emission area EMA3″.

The first to third sub-pixels SP1″ to SP3″ may have polygonal shapes when viewed in a third direction DR3 (e.g., in a plan view). For example, the shapes of the first to third sub-pixels SP1″ to SP3″ may be hexagonal shapes.

The first to third emission areas EMA1″ to EMA3″ may have circular shapes when viewed in the third direction DR3 (e.g., in a plan view). However, the present disclosure is not limited thereto. For example, each of the first to third emission areas EMA1″ to EMA3″ may have a polygonal shape.

The first and third sub-pixels SP1″ and SP3″ may be arranged along the first direction DR1. The second sub-pixel SP2″ may be disposed in a direction (e.g., a diagonal direction) inclined by an acute angle based on the second direction DR2, with respect to the first sub-pixel SP1″.

The arrangements of the sub-pixels, which are described above with reference to FIGS. 4 to 6, are representative examples, and the present disclosure is not limited thereto. Each pixel may include two or more sub-pixels, and the sub-pixels may be arranged in various suitable forms. Each of the sub-pixels may have various suitable shapes, and an emission area of the sub-pixel may have various suitable shapes.

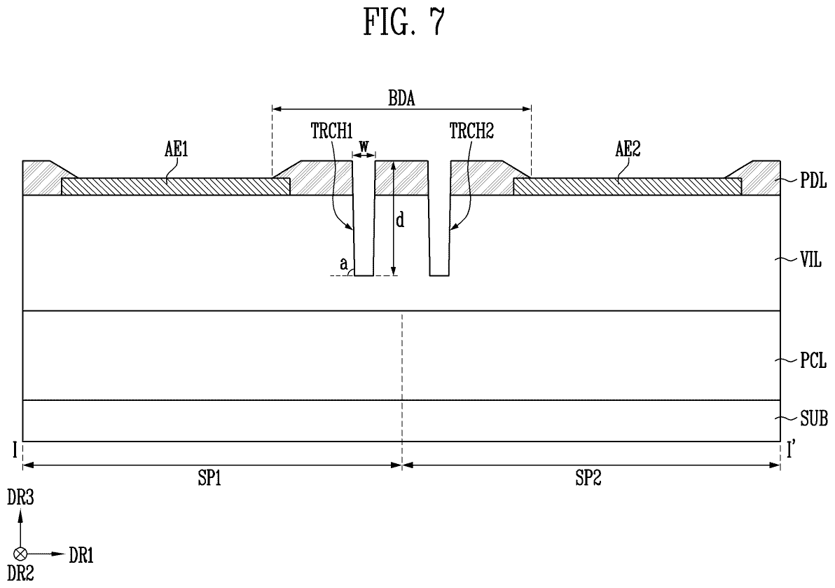

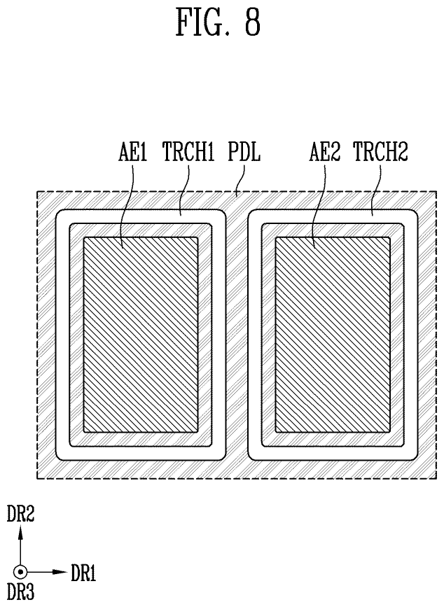

FIG. 7 is a sectional view taken along the line I-I′ of FIG. 4 in accordance with an embodiment of the present disclosure. FIG. 8 is a plan view of anodes and trenches in accordance with an embodiment of the present disclosure. In FIG. 8, a planar structure of first and second anodes AE1 and AE2 and first and second trenches TRCH1 and TRCH2, which are shown in FIG. 7, is schematically illustrated.

Referring to FIG. 7, a substrate SUB may be provided. The substrate SUB may be a silicon wafer substrate formed using a semiconductor process. For example, the substrate SUB may include silicon, germanium, and/or silicon-germanium. However, the present disclosure is not limited thereto. For example, the substrate SUB may be a glass substrate or a polyimide (PI) substrate.

A pixel circuit layer PCL may be disposed (e.g., may be formed) on the substrate SUB. The pixel circuit layer PCL may include circuit elements of the first and second sub-pixels SP1 and SP2. For example, the pixel circuit layer PCL may include transistors and one or more capacitors included in a sub-pixel circuit SPC (e.g., see FIG. 2) of the first sub-pixel SP1, and transistors and one or more capacitors included in a sub-pixel circuit SPC of the second sub-pixel SP2.

A via layer VIL may be disposed (e.g., may be formed) on the pixel circuit layer PCL. The via layer VIL may planarize or substantially planarize step differences on the pixel circuit layer PCL. For example, the via layer VIL covers the pixel circuit layer PCL, and may have an entirely flat or substantially flat surface. The via layer VIL may include at least one of silicon oxide (SiOₓ), silicon nitride (SiNₓ), and silicon carbon nitride (SiCN), but the present disclosure is not limited thereto.

The first and second anodes AE1 and AE2 may be disposed (e.g., may be formed) on the via layer VIL to be spaced apart from each other. The first anode AE1 may be included in the first sub-pixel SP1, and the second anode AE2 may be included in the second sub-pixel SP2. The first anode AE1 may be connected to the sub-pixel circuit SPC of the first sub-pixel SP1, which is included in the pixel circuit layer PCL, through a first contact hole penetrating the via layer VIL. The second anode AE2 may be connected to the sub-pixel circuit SPC of the second sub-pixel SP2, which is included in the pixel circuit layer PCL, through a second contact hole penetrating the via layer VIL. For example, the first and second anodes AE1 and AE2 may include at least one of indium tin oxide (ITO), indium zinc oxide (IZO), zinc oxide (ZnO), indium gallium zinc oxide (IGZO), and indium tin zinc oxide (ITZO). The first and second anodes AE1 and AE2 may have a single-layer structure or a multi-layered structure including one or more of the above-described materials. However, the present disclosure is not limited thereto.

A pixel-defining layer PDL may be disposed (e.g., may be formed) on portions (e.g., edges) of the first and second anodes AE1 and AE2 and the via layer VIL. The pixel-defining layer PDL may include openings partially exposing the first and second anodes AE1 and AE2. The pixel-defining layer PDL may have an entirely flat or substantially flat surface. The pixel-defining layer PDL may include an inorganic insulating material. For example, the pixel-defining layer PDL may include at least one of silicon oxide (SiOₓ) and silicon nitride (SiNₓ). However, the present disclosure is not limited thereto. For example, the pixel-defining layer PDL may include at least one organic insulating material from among polyimide, polyamide, acrylic resin, benzocyclobutene resin, and/or phenolic resin. The pixel-defining layer PDL may have a single-layer structure or a multi-layered structure including one or more of the above-described materials.

The first and second trenches TRCH1 and TRCH2 may be located in a boundary area BDA between the first sub-pixel SP1 and the second sub-pixel SP2. For example, the first and second trenches TRCH1 and TRCH2 may be located between the first anode AE1 and the second anode AE2. Referring to FIG. 8, the first and second trenches TRCH1 and TRCH2 may be formed corresponding to the first and second anodes AE1 and AE2, respectively. For example, the first and second 1 trenches TRCH1 and TRCH2 may surround (e.g., around peripheries of) the first and second anodes AE1 and AE2, respectively. The first and second trenches TRCH1 and TRCH2 may be spaced apart from each other.

In FIG. 7, two trenches TRCH1 and TRCH2 are illustrated in the boundary area BDA. However, the present disclosure is not limited thereto. For example, one trench may be provided in the boundary area BDA. As another example, three or more trenches may be provided in the boundary area BDA.

Each of the first and second trenches TRCH1 and TRCH2 may be formed by etching a portion of the via layer VIL and the pixel-defining layer PDL. For example, each of the first and second trenches TRCH1 and TRCH2 may partially penetrate the via layer VIL, and may entirely penetrate the pixel-defining layer PDL.

The first and second trenches TRCH1 and TRCH2 may have a tapered shape. For example, the first and second trenches TRCH1 and TRCH2 may have a tapered shape having a width that increases in the third direction DR3 (e.g., the thickness direction). The first and second trenches TRCH1 and TRCH2 may be formed under the same process condition as each other. In other words, the first and second trenches TRCH1 and TRCH2 may have the same specifications as each other. Accordingly, the specifications of the first trench TRCH1 are illustrated in FIG. 7 as a representative example.

Taper angles a of the first and second trenches TRCH1 and TRCH2 may be 85 degrees or more and less than 90 degrees. The taper angles a may be a factor for determining a height and a shape of first and second voids VD1 and VD2 (e.g., see FIG. 9). When the taper angles a satisfy the above-described range, the first and second voids VD1 and VD2 having a shape extending in the third direction DR3 (e.g., the thickness direction) and a sufficient height may be formed, such that a first charge generation layer CGL1 (e.g., see FIG. 9) and a second charge generation layer CGL2 (e.g., see FIG. 9) may have a discontinuous structure.

Aspect ratios of the first and second trenches TRCH1 and TRCH2 may be greater than 4. The aspect ratio may be defined as a value obtained by dividing a depth d (e.g., a thickness) of the first and second trenches TRCH1 and TRCH2 by a width w of a top surface of each of the first and second trenches TRCH1 and TRCH2. In other words, the aspect ratio may be equal to the depth over the width (e.g., d/w). When the aspect ratio satisfies the above-described range, a leakage current between the first sub-pixel SP1 and the second sub-pixel SP2 may be reduced (or eliminated). For example, the leakage current may be reduced to 0.1% or less. Experimentally, when the aspect ratio is 5.4, the leakage current is considerably reduced to 0.06%. On the other hand, when the aspect ratio is 3.1, the leakage current is very considerably large as 0.43%.

The width w of the top surface of each of the first and second trenches TRCH1 and TRCH2 may be 80 nm to 130 nm. The width (w) of the top surface may be a factor for determining the height of the first and second voids VD1 and VD2. When the width w of the top surface satisfies the above-described range, the first and second voids VD1 and VD2 having a sufficient height may be formed, such that the first charge generation layer CGL1 (e.g., see FIG. 9) and the second charge generation layer CGL2 (e.g., see FIG. 9) may have the discontinuous structure. The width (w) of the top surface may be referred to as a critical dimension.

The depth d (e.g., the thickness) of each of the first and second trenches TRCH1 and TRCH2 may be 600 nm or more. The depth d (e.g., the thickness) may be a factor for determining a discontinuous structure of a p-type hole injection layer PHIL (e.g., see FIG. 9). When the depth d satisfies the above-described range, the p-type hole injection layer PHIL may have the discontinuous structure. Experimentally, when the depth (d) is 687 nm, the p-type hole injection layer PHIL is cut and has the discontinuous structure. On the other hand, when the depth d is 385 nm, the p-type hole injection layer PHIL is not cut and has a continuous structure.

Sub-pixels adjacent to each other (e.g., the first and second sub-pixels SP1 and SP2) have been described above. The sub-pixels adjacent to each other (e.g., the first and second sub-pixels SP1 and SP2), which are described above with reference to FIG. 4, and the first and third sub-pixels SP1 and SP3 may be configured the same or substantially the same as within the above described range, and thus, redundant description thereof may not be repeated.

FIG. 9 is a sectional view taken along the line I-I′ of FIG. 4 in accordance with an embodiment of the present disclosure. In FIG. 9, redundant description of the portions described above with reference to FIG. 7 may not be repeated or may be simplified.

Referring to FIG. 9, a light-emitting structure EMS may be disposed on the first and second anodes AE1 and AE2 and the pixel-defining layer PDL. The light-emitting structure EMS may include a p-type hole injection layer PHIL, a first light-emitting structure EMS1, a first charge generation layer CGL1, a second light-emitting structure EMS2, a second charge generation layer CGL2, and a third light-emitting structure EMS3, which are stacked along the third direction DR3 (e.g., the thickness direction). In other words, the light-emitting structure EMS may have a three-layer stacked tandem structure.

The p-type hole injection layer PHIL may include a hole injection material and a p-type dopant. However, the hole injection material and the p-type dopant are not particularly limited. The p-type hole injection layer PHIL may function to smoothly inject holes provided from the first and second anodes AE1 and AE2 into the first light-emitting structure EMS1. The p-type hole injection layer PHIL may be disposed on the first and second anodes AE1 and AE2 and the pixel-defining layer PDL. The p-type hole injection layer PHIL may have a discontinuous structure in the boundary area BDA by the first and second trenches TRCH1 and TRCH2. For example, the p-type hole injection layer PHIL may be disposed on side surfaces of the pixel-defining layer PDL, and may extend therefrom to be partially disposed on side surfaces of the via layer VIL. Because the first and second trenches TRCH1 and TRCH2 have a sufficient depth d (e.g., or thickness) (e.g., see FIG. 7), the p-type hole injection layer PHIL may not be entirely formed on the via layer VIL, and may be cut in a process in which the p-type hole injection layer PHIL is deposited. Accordingly, a leakage current between the first and second sub-pixels SP1 and SP2 through the p-type hole injection layer PHIL may be reduced (or eliminated).

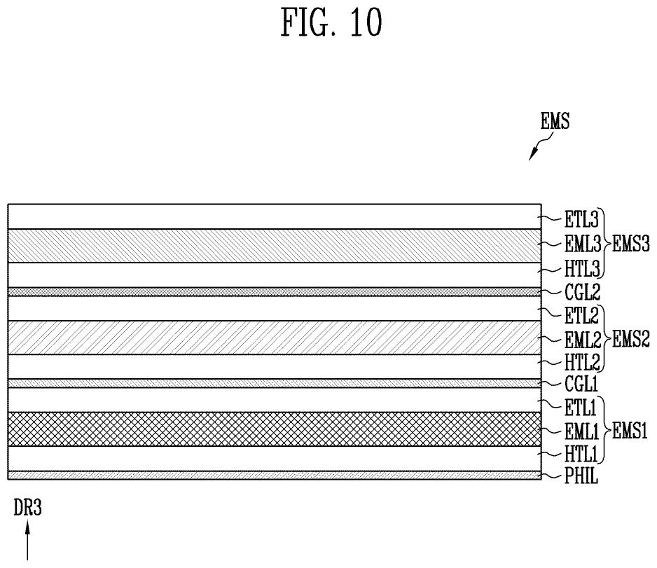

The first light-emitting structure EMS1 may be disposed on the p-type hole injection layer PHIL. The first light-emitting structure EMS1 may emit light of a first color (e.g., light of a red color). The first light-emitting structure EMS1 will be described in more detail below with reference to FIG. 10.

The first charge generation layer CGL1 may be disposed on the first light-emitting structure EMS1. The first charge generation layer CGL1 may include an n-type charge generation layer and a p-type charge generation layer, which are stacked in the third direction DR3 (e.g., the thickness direction). The n-type charge generation layer of the first charge generation layer CGL1 may function to supply electrons to the first light-emitting structure EMS1. The p-type charge generation layer of the first charge generation layer CGL1 may function to supply holes to the second light-emitting structure EMS2. The first charge generation layer CGL1 may have a discontinuous structure in the boundary area BDA by the first and second voids VD1 and VD2 formed corresponding to the first and second trenches TRCH1 and TRCH2, respectively. For example, the first charge generation layer CGL1 may be cut by the first and second voids VD1 and VD2 in a process in which the first charge generation layer CGL1 is deposited on the first light-emitting structure EMS1. Accordingly, a leakage current between the first and second sub-pixels SP1 and SP2 through the first charge generation layer CGL1 may be reduced (or eliminated).

The second light-emitting structure EMS2 may be disposed on the first charge generation layer CGL1. The second light-emitting structure EMS2 may emit light of a second color (e.g., light of a blue color). The second light-emitting structure EMS2 will be described in more detail below with reference to FIG. 10.

The second charge generation layer CGL2 may be disposed on the second light-emitting structure EMS2. The second charge generation layer CGL2 may include an n-type charge generation layer and a p-type charge generation layer, which are stacked in the third direction DR3 (e.g., the thickness direction). The n-type charge generation layer of the second charge generation layer CGL2 may function to supply electrons to the second light-emitting structure EMS2. The p-type charge generation layer of the second charge generation layer CGL2 may function to supply holes to the third light-emitting structure EMS3. The second charge generation layer may have a discontinuous structure in the boundary area BDA by the first and second voids VD1 and VD2. For example, the second charge generation layer CGL2 may be cut by the first and second voids VD1 and VD2 in a process in which the second charge generation layer CGL2 is deposited on the second light-emitting structure EMS2. Accordingly, a leakage current between the first and second sub-pixels SP1 and SP2 through the second charge generation layer CGL2 may be reduced (or eliminated).

As described above, in the boundary area BDA, the p-type hole injection layer PHIL may be cut by the first and second trenches TRCH1 and TRCH2, and the first and second charge generation layers CGL1 and CGL2 may be cut by the first and second voids VD1 and VD2. Thus, a leakage current between the first and second sub-pixels SP1 and SP2 through the p-type hole injection layer PHIL, the first charge generation layer CGL1, and the second charge generation layer CGL2, which have a relatively high conductivity, may be reduced (or eliminated).

The third light-emitting structure EMS3 may be disposed on the second charge generation layer CGL2. The third light-emitting structure EMS3 may emit light of a third color (e.g., light of a green color). The third light-emitting structure EMS3 will be described in more detail below with reference to FIG. 10.

A cathode CE may be disposed on the light-emitting structure EMS. The cathode CE may be formed to be substantially transparent or translucent to satisfy a desired light transmittance (e.g., a predetermined light transmittance). For example, the cathode CE may include at least one of various suitable transparent conductive materials, such as indium tin oxide (ITO), zinc oxide (ZnO), indium gallium zinc oxide (IGZO), and indium tin zinc oxide (ITZO). The cathode CE may have a single-layer structure or a multi-layered structure including one or more of the above-described materials. However, the present disclosure is not limited thereto.

A capping layer CPL may be disposed on the cathode CE. The capping layer CPL may protect the components under the capping layer CPL, such as the cathode CE and the light-emitting structure EMS, from external moisture, humidity, and the like. The capping layer CPL may include at least one of silicon nitride (SiNₓ), silicon oxide (SiOₓ), silicon oxynitride (SiOₓN_{y}), and a metal oxide, such as aluminum oxide (AlOₓ). However, the present disclosure is not limited thereto.

An encapsulation layer TFE may be disposed on the capping layer CPL. The encapsulation layer TFE may prevent or substantially prevent the infiltration of oxygen and/or moisture. The encapsulation layer TFE may include a structure in which one or more inorganic layers and one or more organic layers are alternately stacked. For example, the inorganic layer may include an inorganic insulating material, such as silicon nitride (SiNₓ), silicon oxide (SiOₓ), or silicon oxynitride (SiOₓN_{y}). For example, the organic layer may include an organic insulating material, such as an acrylic resin, an epoxy resin, a phenolic resin, a polyamide resin, a polyimide resin, an unsaturated polyester resin, a polyphenylether resin, a polyphenylenesulfide resin, or benzocyclobutene (BCB) resin. However, the present disclosure is not limited thereto.

FIG. 10 is a sectional view of a light-emitting structure in accordance with an embodiment of the present disclosure. In FIG. 10, redundant description of the portions described above with reference to FIG. 7 may not be repeated or may be simplified.

Referring to FIG. 10, the first light-emitting structure EMS1 of the light-emitting structure EMS may include a first hole transport layer HTL1, a first light-emitting layer EML1, and a first electron transport layer ETL1, which are stacked in the third direction DR3 (e.g., the thickness direction). The first hole transport layer HTL1 may include a hole transport material, and may function to smoothly transport holes injected from the p-type hole injection layer PHIL to the first light-emitting layer EML1. However, the hole transport material is not particularly limited. The first light-emitting layer EML1 may include a light-emitting material for generating light of a first color (e.g., light of a red color). The first electron transport layer ETL1 may include an electron transport material, and may function to smoothly transport electrons injected from the first charge generation layer CGL1 to the first light-emitting layer EML1. However, the electron transport material is not particularly limited.

The second light-emitting structure EMS2 of the light-emitting structure EMS may include a second hole transport layer HTL2, a second light-emitting layer EML2, and a second electron transport layer ETL2, which are stacked in the third direction DR3 (e.g., the thickness direction). The second hole transport layer HTL2 may function to smoothly transport holes injected from the first charge generation layer CGL1 to the second light-emitting layer EML2. The second hole transport layer HTL2 may include (e.g., may be made of or substantially made of) the same material as that of the first hole transport layer HTL1. The second light-emitting layer EML2 may include a light-emitting material for generating light of a second color (e.g., light of a blue color). The second electron transport layer ETL2 may function to smoothly transport electrons injected from the second charge generation layer CGL2 to the second light-emitting layer EML2. The second electron transport layer ETL2 may include (e.g., may be made of or substantially made of) the same material as that of the first electron transport layer ETL1.

The third light-emitting structure EMS3 of the light-emitting structure EMS may include a third hole transport layer HTL3, a third light-emitting layer EML3, and a 1 third electron transport layer ETL3, which are stacked in the third direction DR3 (e.g., the thickness direction). The third hole transport layer HTL3 may function to smoothly transport holes injected from the second charge generation layer CGL2 to the third light-emitting layer EML3. The third hole transport layer HTL3 may include (e.g., may be made of or substantially made of) the same material as that of the first hole transport layer HTL1. The third light-emitting layer EML3 may include a light-emitting material for generating light of a third color (e.g., light of a green color). The third electron transport layer ETL3 may function to smoothly transport electrons injected from the cathode CE (e.g., see FIG. 9) to the third light-emitting layer EML3. The third electron transport layer ETL3 may include (e.g., may be made of or substantially made of) the same material as that of the first electron transport layer ETL1.

The light-emitting material included in each of the first to third light-emitting layers EML1 to EML3 may include at least one of an organic light-emitting material, an inorganic light-emitting material, an organic/inorganic light-emitting material, and a quantum dot, but the present disclosure is not limited thereto.

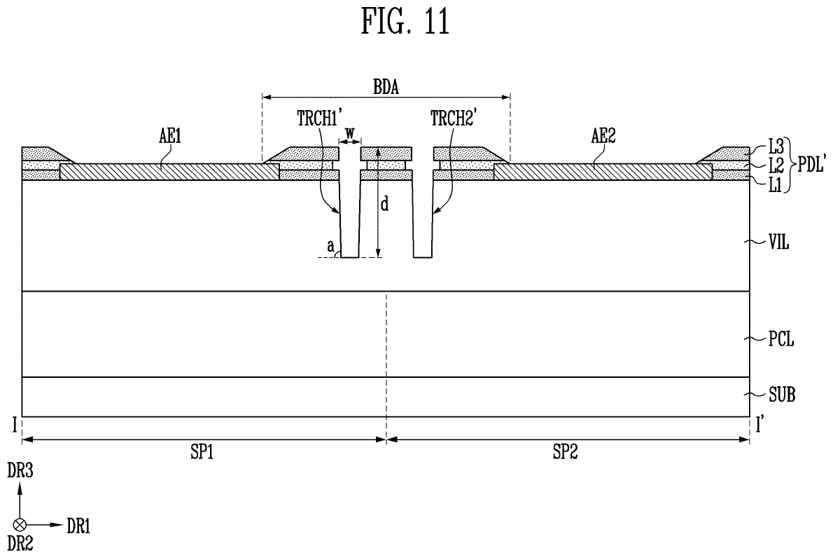

FIG. 11 is a sectional view taken along the line I-I′ of FIG. 4 in accordance with an embodiment of the present disclosure. In FIG. 11, redundant description of the portions described above with reference to FIG. 7 may not be repeated or may be simplified.

Referring to FIG. 11, a pixel-defining layer PDL′ may have a triple-layered structure. For example, the pixel-defining layer PDL′ may include a first layer L1, a second layer L2, and a third layer L3, which are stacked in the third direction DR3 (e.g., the thickness direction). The first to third layers L1 to L3 may include (e.g., may be made of) an inorganic insulating material. For example, the first layer L1 may include silicon oxide (SiOₓ), the second layer L2 may include silicon nitride (SiNₓ), and the third layer L3 may include silicon oxide (SiOₓ). The pixel-defining layer PDL′ having the triple-layered structure may have an entirely flat or substantially flat surface.

First and second trenches TRCH1′ and TRCH2′ may be formed by etching a portion of the via layer VIL and the pixel-defining layer PDL′. The second layer L2 and the third layer L3 may form an undercut structure in a process of forming the first and second trenches TRCH1′ and TRCH2′. For example, side surfaces of the third layer L3 may protrude outwardly (e.g., in the first direction DR1 or the opposite direction of the first direction DR1) from side surfaces of the second layer L2. In other words, the side surfaces of the second layer L2 may be disposed inwardly from the side surfaces of the third layer L3 to form the undercut structure. Therefore, the first and second trenches TRCH1′ and TRCH2′ may have a shape similar to (e.g., close to) a cross shape on a section (e.g., in a cross-sectional view).

Unlike the first and second trenches TRCH1 and TRCH2 described above with reference to FIG. 7, the first and second trenches TRCH1′ and TRCH2′ may be formed inside the pixel-defining layer PDL′ (e.g., in the second layer L2). The p-type hole injection layer PHIL (e.g., see FIG. 9) may be more effectively cut in the boundary area BDA by the first and second trenches TRCH1′ and TRCH2′ in a deposition process. In other words, the discontinuous structure of the p-type hole injection layer PHIL may be further reinforced. Accordingly, a leakage current between the first and second sub-pixel SP1 and SP2 through the p-type hole injection layer PHIL may be more effectively reduced (or eliminated).

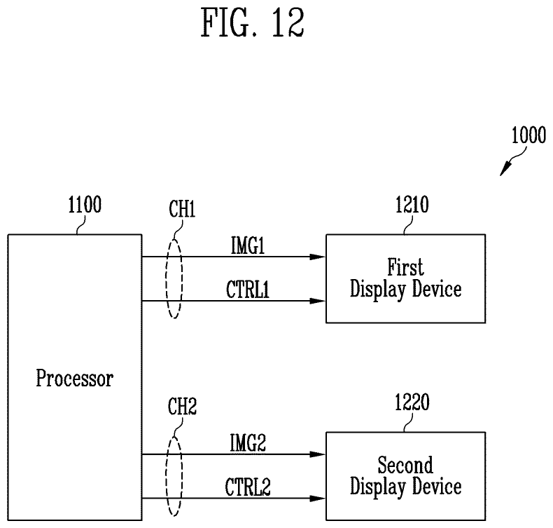

FIG. 12 is a block diagram of a display system in accordance with an embodiment of the present disclosure.

Referring to FIG. 12, a display system 1000 may include a processor 1100 and one or more display devices 1210 and 1220.

The processor 1100 may perform various suitable tasks and various suitable calculations. The processor 1100 may include an Application Processor (AP), a Graphics Processing Unit (GPU), a microprocessor, a Central Processing Unit (CPU), and/or the like. The processor 1100 may be connected to the other components of the 1 display system 1000 through a bus system to control the components of the display system 1000.

The display system 1000 may include first and second display devices 1210 and 1220. The processor 1100 may be connected to the first display device 1210 through a first channel CH1, and may be connected to the second display device 1220 through a second channel CH2.

Through the first channel CH1, the processor 1100 may transmit first image data IMG1 and a first control signal CTRL1 to the first display device 1210. The first display device 1210 may display an image, based on the first image data IMG1 and the first control signal CTRL1. The first display device 1210 may be configured the same or substantially the same as that of the display device 100 described above with reference to FIG. 1. The first image data IMG1 and the first control signal CTRL1 may be provided as the input image data IMG and the control signal CTRL, respectively, which are described above with reference to FIG. 1.

Through the second channel CH2, the processor 1100 may transmit second image data IMG2 and a second control signal CTRL2 to the second display device 1220. The second display device 1220 may display an image, based on the second image data IMG2 and the second control signal CTRL2. The second display device 1220 may be configured the same or substantially the same as that of the display device 100 described above with reference to FIG. 1. The second image data IMG2 and the second control signal CTRL2 may be provided as the input image data IMG and the control signal CTRL, respectively, which are described above with reference to FIG. 1.

The display system 1000 may include a computing system for providing an image display function, such as a portable computer, a mobile phone, a smartphone, a tablet personal computer (PC), a smart watch, a watch phone, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

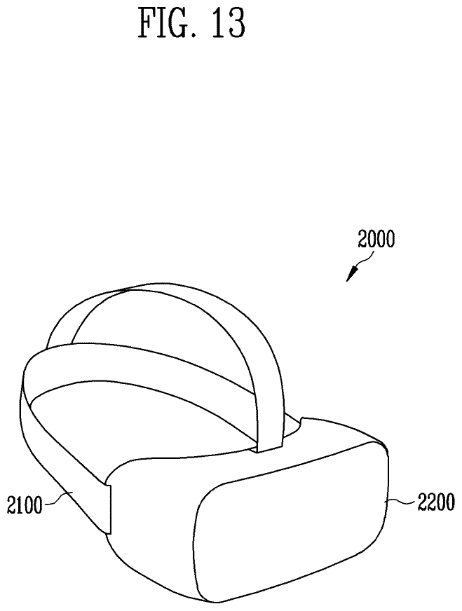

FIG. 13 is a perspective view of a head-mounted display device in accordance with an embodiment of the present disclosure.

Referring to FIG. 13, the display system 1000 described above with reference to FIG. 12 may be applied to the head mounted display device 2000. The head mounted display device 2000 may be a wearable electronic device that can be worn on the head of a user.

The head mounted display device 2000 may include a head mounting band 2100 and a display device accommodating case 2200. The head mounting band 2100 may be connected to the display device accommodating case 2200. The head mounting band 2100 may include a horizontal band and/or a vertical band, which may be used to fix the head mounted display device 2000 to the head of the user. The horizontal band may be configured to surround (e.g., around a periphery of) a side portion of the head of the user, and the vertical band may be configured to surround (e.g., around a periphery of) an upper portion of the head of the user. However, the present disclosure is not limited thereto. For example, the head mounting band 2100 may be implemented in the form of a glasses frame, a helmet, or the like.

The display device accommodating case 2200 may accommodate the first and second display devices 1210 and 1220 described above with reference to FIG. 12. The display device accommodating case 2200 may further accommodate the processor 1100 described above with reference to FIG. 12.

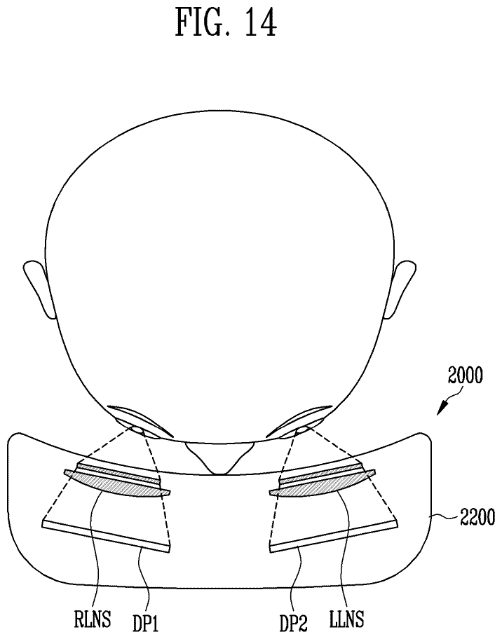

FIG. 14 is a view illustrating the head-mounted display device shown in FIG. 13 that is worn by a user in accordance with an embodiment of the present disclosure.

Referring to FIG. 14, a first display panel DP1 of the first display device 1210 and a second display panel DP2 of the second display device 1220 may be disposed in the head mounted display device 2000. The head mounted display device 2000 may further include one or more lenses LLNS and RLNS.

In the display device accommodating case 2200, a right-eye lens RLNS may be disposed between the first display panel DP1 and a right eye of the user. In the display device accommodating case 2200, a left-eye lens LLNS may be disposed between the second display panel DP2 and a left eye of the user.

An image output from the first display panel DP1 may be viewed by the right eye of the user through the right-eye lens RLNS. The right-eye lens RLNS may refract light emitted from the first display panel DP1 to face the right eye of the user. The right-eye lens RLNS may perform an optical function for adjusting a viewing distance between the first display panel DP1 and the right eye of the user.

An image output from the second display panel DP2 may be viewed by the left eye of the user through the left-eye lens LLNS. The left-eye lens LLNS may refract light emitted from the second display panel DP2 to face the left eye of the user. The left-eye lens LLNS may perform an optical function for adjusting a viewing distance between the second display panel DP2 and the left eye of the user.

Each of the right-eye lens RLNS and the left-eye lens LLNS may include an optical lens having a pancake-shaped section. Each of the right-eye lens RLNS and the left-eye lens LLNS may include a multi-channel lens including sub-areas having different optical characteristics. Each display panel DP1 and DP2 may output images respectively corresponding to the sub-areas of the multi-channel lens, and the output images may be viewed by the user while respectively passing through corresponding sub-areas.

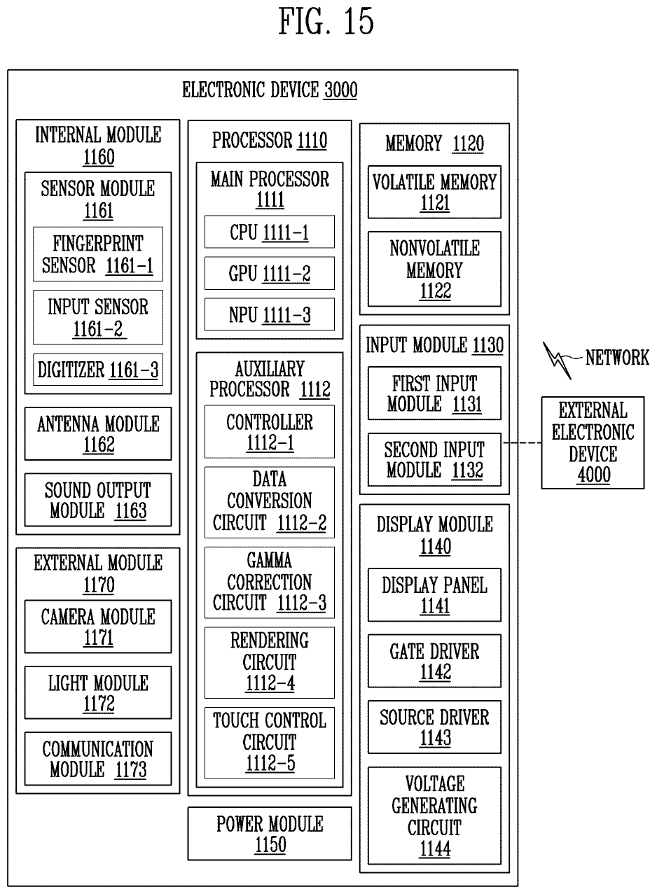

FIG. 15 is a block diagram of an electronic device in accordance with an embodiment of the present disclosure.

Referring to FIG. 15, an electronic device 3000 may output various information through a display module 1140. When a processor 1110 executes an application stored in a memory 1120, the display module 1140 may provide application information to a user through a display panel 1141.

The processor 1110 may acquire an external input through an input module 1130 or a sensor module 1161, and execute an application corresponding to the external input.

For example, when the user selects a camera icon (or camera application icon) displayed on the display panel 1141, the processor 1110 may acquire a user input through an input sensor 1161-2, and activate a camera module 1171. The processor 1110 may transfer, to the display module 1140, image data corresponding to a photographed image acquired through the camera module 1171. The display module 1140 may display an image corresponding to the photographed image through the display panel 1141.

For example, when personal information authentication is executed in the display module 1140, a fingerprint sensor 1161-1 may acquire input fingerprint information as input data. The processor 1110 may compare the input data acquired through the fingerprint sensor 1161-1 with authentication data stored in the memory 1120, and execute an application according to a comparison result. The display module 1140 may display information executed according to a logic of the application through the display panel 1141. The fingerprint sensor 1161-1 may be disposed to acquire fingerprint information in the entire area of the display panel 1141.

For example, when a music streaming icon displayed on the display module 1140 is selected, the processor 1110 may acquire a user input through the input sensor 1161-2, and active a music streaming application stored in the memory 1120. When a music play command is input in the music streaming application, the processor 1110 may activate a sound output module 1163, thereby providing the user with sound information which accords with the music play command.

In the above, operations of the electronic device 3000 have been briefly described. Hereinafter, components of the electronic device 3000 will be described in more detail. Some of the components of the electronic device 3000, which will be 1 described further below, may be integrated to be provided as one component, and one component may be separated into two or more components to be provided.

The electronic device 3000 may communicate with an external electronic device 4000 through a network (e.g., a short-range wireless communication network or a long-range wireless communication network). The electronic device 3000 may include the processor 1110, the memory 1120, the input module 1130, the display module 1140, a power module 1150, an internal module 1160, and an external module 1170. In the electronic device 3000, at least one of the above-described components may be omitted, or one or more other components may be added. Some components (e.g., the sensor module 1161, an antenna module 1162, and/or the sound output module 1163) among the above-described components may be integrated in another component (e.g., the display module 1140).

The processor 1110 may control at least another component (e.g., a hardware or software component) of the electronic device 3000, which is connected to the processor 1110, by executing software, and perform various processing or calculations. As at least a portion of the data processing and calculations, the processor 1110 may store, in a volatile memory 1121, a command or data, received from another component (e.g., the input module 1130, the sensor module 1161, or a communication module 1173), process the command or data, stored in the volatile memory 1121, and store result data in a nonvolatile memory 1122.

The processor 1110 may include a main processor 1111 and an auxiliary processor 1112. The main processor 1111 may include a central processing unit (CPU) 1111-1. The main processor 1111 may further include at least one of a graphic processing unit (GPU) 1111-2, a communication processor (CP), and an image signal processor (ISP). The main processor 1111 may further include a neural processing unit (NPU) 1111-3. The NPU 1111-3 is a processor specified for processing an artificial intelligence (AI) model, and the AI model may be generated through machine learning. The AI model may include a plurality of artificial neural network layers. An 1 artificial neural network may be a deep neural network (DNN), a convolutional neural network (CNN), a recurrent neural network (RNN), a restricted boltzman machine (RBM), a deep belief network (DBN), a bidirectional recurrent deep neural network (BRDNN), a deep Q-networks, and one of two or more combinations thereof, but the present disclosure is not limited thereto. The AI model may additionally or alternatively include a software structure, in addition to a hardware structure. At least two of the above-described processing units and the above-described processors may be implemented into one integrated component (e.g., a single chip), or be implemented as components (e.g., a plurality of chips) independent from each other.

The auxiliary processor 1112 may include a controller 1112-1. The controller 1112-1 may include an interface conversion circuit and a timing control circuit. For example, the auxiliary processor 1112 may include the controller 150 described above with reference to FIG. 1. The controller 1112-1 may receive an image signal from the main processor 1111, and output image data by converting a data format of the image signal to be suitable for interface specifications with the display module 1140. The controller 1112-1 may output various control signals necessary for driving of the display module 1140.

The auxiliary processor 1112 may further include a data conversion circuit 1112-2, a gamma correction circuit 1112-3, a rendering circuit 1112-4, a touch control circuit 1112-5, and the like. The data conversion circuit 1112-2 may receive image data from the controller 1112-1, and compensate for the image data such that an image is displayed with a desired luminance according to a characteristic of the electronic device 3000 or a setting of the user or convert the image data for the purpose of reduction of power consumption, afterimage compensation, or the like.

The gamma correction circuit 1112-3 may convert image data, a gamma reference voltage, or the like such that an image displayed in the electronic device 3000 has a desired gamma characteristic. The rendering circuit 1112-4 may receive image data from the controller 1112-1, and render the image data by considering a pixel arrangement of the display panel 1141, and the like, applied to the electronic device 3000.

The touch control circuit 1112-5 may supply a touch signal to the input sensor 1161-2, and be supplied with a sensing signal from the input sensor 1161-2, corresponding to the touch signal.

At least one of the data conversion circuit 1112-2, the gamma correction circuit 1112-3, the rendering circuit 1112-4, and the touch control circuit 1112-5 may be integrated in another component (e.g., the main processor 1111 or the controller 1112-1). At least one of the data conversion circuit 1112-2, the gamma correction circuit 1112-3, and the rendering circuit 1112-4 may be integrated into a source driver 1143 which will be described later.

The memory 1120 may store various data used by at least one component (e.g., the processor 1110 or the sensor module 1161) of the electronic device 3000 and input or output data about a command associated therewith. Also, various setting data corresponding to the setting of the user stored in the memory 1120. The memory 1120 may include at least one of the volatile memory 1121 and the nonvolatile memory 1122.

The input module 1130 may receive a command or data to be used in a component (e.g., the processor 1110, the sensor module 1161, or the sound output module 1163) of the electronic device 3000 from the outside (e.g., the user or the external electronic device 4000) of the electronic device 3000.

The input module 1130 may include a first input module 1131 to which a command or data is input from the user and a second input module 1132 to which a command or data is input from the external electronic device 4000. The first input module 1131 may include a microphone, a mouse, a keyboard, a key (e.g., a button), or a pen (e.g., a passive pen or an active pen). The second input module 1132 may support a specified protocol capable of connecting the electronic device 3000 to the external electronic device 4000 by wired or wireless. The second input module 1132 may include a high definition multimedia interface (HDMI), a universal serial bus (USB) interface, an SD card interface, or an audio interface. The second input module 1132 may include a connector, e.g., an HDMI connector, a USB connector, an SD card connector, or an audio connector (e.g., a headphone connector), which can physically connect the electronic device 3000 to the external electronic device 4000.

The display module 1140 may visually provide information to the user. The display module 1140 may include the display panel 1141, a gate driver 1142, the source driver 1143, and a voltage generating circuit 1144. The display module 1140 may further include a window for protecting the display panel 1141, a chassis, and a bracket. The display module 1140 may include at least some components of the display device 100 described above with reference to FIG. 1.

The display panel 1141 may include a liquid crystal display panel, an organic light-emitting display panel, or an inorganic light-emitting display panel, and the kind of the display panel 1141 is not particularly limited. The display panel 1141 may be a rigid type or a flexible type in which the display panel 1141 is rollable or foldable. The display module 1140 may further include a supporter for supporting the display panel 1141, a bracket, a heat dissipation member, or the like. The display panel 1141 may include the display panel 110 described above with reference to FIG. 1.

The gate driver 1142 is a driving chip, and may be mounted in the display panel 1141. Also, the gate driver 1142 may be integrated in the display panel 1141. For example, the gate driver 1142 may include an Amorphous Silicon TFT Gate (ASG) driver circuit, a Low Temperature Polycrystalline Silicon (LTPS) TFT gate driver circuit, or an Oxide Semiconductor TFT Gate (OSG) driver circuit, which is embedded in the display panel 1141. The gate driver 1142 may receive a control signal from the controller 1112-1, and output scan signals to the display panel 1141 in response to the control signal. The gate driver 1142 may include the gate driver 120 described above with reference to FIG. 1.

The display module 1140 may further include an emission driver. The emission driver may output an emission control signal to the display panel 1141 in response to a control signal receive from the controller 1112-1. The emission driver may be formed separately from the gate driver 1142, or be integrated in the gate driver 1142.

The source driver 1143 may receive a control signal from the controller 1112-1, and convert image data into an analog voltage (e.g., a data voltage) and then output data voltages to the display panel 1141 in response to the control signal. The source driver 1143 may include the data driver 130 described above with reference to FIG. 1.

The source driver 1143 may be integrated in another component (e.g., the controller 1112-1). Functions of the interface conversion circuit and the timing control circuit of the controller 1112-1, which are described above, may be integrated in the source driver 1143.

The voltage generating circuit 1144 may output various voltages necessary for driving of the display panel 1141. In an example, the voltage generating circuit 1144 may include the voltage generator 140 described above with reference to FIG. 1.

The source driver 1143 may convert data corresponding to red, green, and blue, included in image data received from the processor 1110, into a red data signal (or data voltage), a green data signal, and a blue data signal, and provide the red data signal, the green data signal, and the blue data signal to a plurality of pixel columns included in the display panel 1141 during one horizontal period.

The power module 1150 may supply power to at least one component of the electronic device 3000. The power module 1150 may include a battery for charging a power voltage. The battery may include a primary cell which is not rechargeable, a secondary cell which is rechargeable, or a fuel cell. The power module 1150 may include a power management integrated circuit (PMIC). The PMIC may supply an optimized power source to each of the above-described modules and modules which will be described later. The power module 1150 may include a wireless power transmission/reception member electrically connected to the battery. The wireless power transmission/reception member may include a plurality of coil-shaped antenna radiators. At least some components of the power module 1150 and the voltage generating circuit 1144 may be integrated to be provided as one component. In an example, the voltage generating circuit 1144 may be included in the power module 1150.

The electronic device 3000 may further include the internal module 1160 and the external module 1170. The internal module 1160 may include the sensor module 1161, the antenna module 1162, and the sound output module 1163. The external module 1170 may include the camera module 1171, a light module 1172, and the communication module 1173.

The sensor module 1161 may sense an input caused by a body of the user or an input caused by a pen in the first input module, and generate an electrical signal or a data value, which corresponds to the input. The sensor module 1161 may include at least one of the fingerprint sensor 1161-1, the input sensor 1161-2, and a digitizer 1161-3.

The fingerprint sensor 1161-1 may generate a data value corresponding to a fingerprint of the user.

The input sensor 1161-2 may generate a data value corresponding to coordinate information of the input caused by the body of the user or the input caused by the pen. The input sensor 1161-2 may generate, as a data value, a capacitance variation caused by the input. The input sensor 1161-2 may sense an input caused by a passive pen, or transmit/receive data to/from an active pen.

The input sensor 1161-2 may measure a biometric signal such as pressure, moisture or body fat. For example, when the user does not move for a constant time while a body part of the user is in contact with a sensor layer or a sensing panel, the input sensor 1161-2 may output information which the user wants to the display 1 module 1140 by sensing a biometric signal, based on a change in electric field, caused by the body part.

The digitizer 1161-3 may generate a data value corresponding to the coordinate information of the input caused by the pen. The digitizer 1161-3 may generate, as a data value, an electromagnetic variation caused by the input. The digitizer 1161-3 may sense an input caused by the passive pend, or transmit/receive data to/from the active pen.

At least one of the fingerprint sensor 1161-1, the input sensor 1161-2, and the digitizer 1161-3 may be implemented as a sensor layer formed on the display panel 1141 through a continuous process. At least one of the fingerprint sensor 1161-1, the input sensor 1161-2, and the digitizer 1161-3 may be disposed at an upper side of the display panel 1141, and any one, e.g., the digitizer 1161-3 among the fingerprint sensor 1161-1, the input sensor 1161-2, and the digitizer 1161-3 may be disposed at a lower side of the display panel 1141.

At least two of the fingerprint sensor 1161-1, the input sensor 1161-2, and the digitizer 1161-3 may be formed to be integrated into one sensing panel through the same process. When at least two of the fingerprint sensor 1161-1, the input sensor 1161-2, and the digitizer 1161-3 are integrated into one sensing panel, the sensing panel may be disposed between the display panel 1141 and the window disposed at an upper side of the display panel 1141. The sensing panel may be disposed on the window, and the position of the sensing panel is not particularly limited.

At least one of fingerprint sensor 1161-1, the input sensor 1161-2, and the digitizer 1161-3 may be built in the display panel 1141. That is, at least one of fingerprint sensor 1161-1, the input sensor 1161-2, and the digitizer 1161-3 may be simultaneously formed through a process of forming elements (e.g., a light-emitting element, a transistor, and the like) included in the display panel 1141.

Besides, the sensor module 1161 may generate an electrical signal or a data value, which corresponds to an internal state or an external state of the electronic 1 device 3000. The sensor module 1161 may further include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 1162 may include one or more antennas for transmitting a signal or power to the outside or receiving a signal or power from the outside. In accordance with an embodiment, the communication module 1173 may transmit a signal to the external electronic device or receive a signal from the external electronic device through an antenna suitable for a communication scheme. An antenna pattern of the antenna module 1162 may be integrated in one component (e.g., the display panel 1141) of the display module 1140, the input sensor 1161-2, or the like.

The sound output module 1163 is a device for outputting a sound signal to the outside of the electronic device 3000, and include, for example, a speaker used for a general purpose such as multimedia playback or transcription playback and a receiver used for only call reception. The receiver may be integrally formed with the speaker or be formed separately from the speaker. A sound output pattern of the sound output module 1163 may be integrated in the display module 1140.

The camera module 1171 may photograph a still image and a moving image. The camera module 1171 may include one or more lenses, an image sensor, or an image signal processor. The camera module 1171 may further include an infrared camera capable of measuring existence of the user, a position of the user, eyes of the user, or the like.

The light module 1172 may provide light. The light module 1172 may include a light-emitting diode or a xenon lamp. The light module 1172 may operate in linkage with the camera module 1171 or operate independently from the camera module 1171.

The communication module 1173 may establish a wired or wireless communication channel between the electronic device 3000 and the external electronic device 4000, and support communication performance through the established communication channel. The communication module may include any one or all of a wireless communication module such as a cellular communication module, a short-range wireless communication module, or a global navigation satellite system (GNSS) communication module, and a wired communication module such as a local area network (LAN) communication module or a power line communication (PLC) module. The communication module 1173 may communicate with the external electronic device 4000 through a short-range communication network such as Bluetooth™, wireless-fidelity (WiFi) direct, or infrared data association (IrDA), or a long-range communication network such as a cellular network, Internet, or a computer network (e.g., LAN or wide area network (WAN)). The above-described several kinds of communication modules may be implemented into one chip or be respectively implemented as separate chips.

The input module 1130, the sensor module 1161, the camera module 1171, and the like may be used to control an operation of the display module 1140 in linkage with the processor 1110.

The processor 1110 may output a command or data to the display module 1140, the sound output module 1163, the camera module 1171, or the light module 1172, based on input data received from the input module 1130. For example, the processor 1110 may generate image data, corresponding to input data applied through a mouse, an active pen, or the like, and output the image data to the display module 1140. Alternatively, the processor 1110 may generate command data, corresponding to the input data, and output the command data to the camera module 1171 or the light module 1172. When no input data is received from the input module 1130, the processor 1110 may change the operation mode of the electronic device 3000 to a low power mode or a sleep mode, thereby reducing power consumed in the electronic device 3000.

The processor 1110 may output a command or data to the display module 1140, the sound output module 1163, the camera module 1171, or the light module 1172, based on sensing data received from the sensor module 1161. For example, the processor 1110 may compare authentication data applied by the fingerprint sensor 1161-1 with authentication data stored in the memory 1120, and then execute an application according to a comparison result. The processor 1110 may execute a command or output corresponding image data to the display module 1140, based on sensing data sensed by the input sensor 1161-2 or the digitizer 1161-3. When a temperature sensor is included in the sensor module 1161, the processor 1110 may receive temperature data about a temperature measured from the sensor module 1161, and further perform luminance correction on image data, based on the temperature data.

The processor 1110 may receive measurement data about existence of the user, a position of the user, eyes of the user, or the like from the camera module 1171. The processor 1110 may further perform luminance correction on image data, based on the measurement data. For example, the process 1110 which decides the existence of the user through an input from the camera module 1171 may output image data of which luminance is corrected to the display module 1140 through the data conversion circuit 1112-2 or the gamma correction circuit 1112-3.

In accordance with some embodiments of the present disclosure, a display device, a method of manufacturing the same, and an electronic device may be provided, in which a leakage current between sub-pixels may be reduced (or eliminated).

However, the aspects and features of the present disclosure are not limited to those described above, and various other aspects and features as would be understood by those having ordinary skill in the art may be included in the present disclosure.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a via layer on a pixel circuit layer;
anodes spaced from each other on the via layer;
a pixel-defining layer on the via layer and on edges of the anodes; and
trenches corresponding to the anodes, respectively, and spaced from each other, each of the trenches penetrating a portion of the via layer and the pixel-defining layer,
wherein aspect ratios of the trenches are greater than 4.

2. The display device of claim 1, wherein the trenches have a tapered shape having a width that increases in a thickness direction.

3. The display device of claim 2, wherein a width of a top surface of each of the trenches is 80 nm to 130 nm.

4. The display device of claim 2, wherein thicknesses of the trenches are about 600 nm or more.

5. The display device of claim 2, wherein taper angles of the trenches are about 85 degrees or more and less than about 90 degrees.

6. The display device of claim 1, wherein the pixel-defining layer comprises a triple-layered structure.

7. The display device of claim 6, wherein the triple-layered structure of the pixel-defining layer comprises:
a first layer comprising silicon oxide;
a second layer on the first layer, and comprising silicon nitride; and
a third layer on the second layer, and comprising silicon oxide.

8. The display device of claim 7, wherein the second layer and the third layer form an undercut structure by the trenches.

9. The display device of claim 1, wherein the trenches surround around the anodes, respectively.

10. The display device of claim 1, further comprising:
a light-emitting structure on the anodes and the pixel-defining layer;
a cathode on the light-emitting structure;
a capping layer on the cathode; and
an encapsulation layer on the capping layer.

11. The display device of claim 10, wherein the light-emitting structure comprises:
a p-type hole injection layer;
a first light-emitting structure on the p-type hole injection layer;
a first charge generation layer on the first light-emitting structure;
a second light-emitting structure on the first charge generation layer;
a second charge generation layer on the second light-emitting structure; and
a third light-emitting structure on the second charge generation layer.

12. The display device of claim 11, wherein the first light-emitting structure comprises:
a first hole transport layer;
a first light-emitting layer on the first hole transport layer, and configured to emit light of a red color; and
a first electron transport layer on the first light-emitting layer,
wherein the second light-emitting structure comprises:
a second hole transport layer;
a second light-emitting layer on the second hole transport layer, and configured to emit light of a blue color; and
a second electron transport layer on the second light-emitting layer, and wherein the third light-emitting structure comprises:
a third hole transport layer;
a third light-emitting layer on the third hole transport layer, and configured to emit light of a green color; and
a third electron transport layer on the third light-emitting layer.

13. The display device of claim 11, wherein the p-type hole injection layer has a discontinuous structure by the trenches, and
wherein the first charge generation layer and the second charge generation layer have a discontinuous structure by voids respectively corresponding to the trenches.

14. A method of manufacturing a display device, the method comprising:
forming a via layer on a pixel circuit layer;
forming anodes spaced from each other on the via layer;
forming a pixel-defining layer on the via layer and on edges of the anodes; and
forming trenches surrounding around the anodes, respectively, the trenches being spaced from each other by etching portions of the via layer and the pixel-defining layer,
wherein aspect ratios of the trenches are greater than 4.

15. The method of claim 14, wherein the trenches have a tapered shape having a width that increases in a thickness direction.

16. The method of claim 14, wherein a width of a top surface of each of the trenches is 80 nm to 130 nm.

17. The method of claim 14, wherein thicknesses of the trenches is about 600 nm or more.

18. The method of claim 14, wherein taper angles of the trenches are about 85 degrees or more and less than about 90 degrees.

19. The method of claim 14, wherein the pixel-defining layer comprises:
a first layer comprising silicon oxide;
a second layer on the first layer, and comprising silicon nitride; and
a third layer on the second layer, and comprising silicon oxide, and
wherein the second layer and the third layer form an undercut structure by the trenches.

20. An electronic device comprising:
a display panel;
a processor configured to drive the display panel; and
a voltage generating circuit configured to supply a voltage of a driving power source to the display panel,
wherein the display panel comprises:
a via layer on a pixel circuit layer;
anodes spaced from each other on the via layer;
a pixel-defining layer on the via layer and on edges of the anodes; and
trenches corresponding to the anodes, respectively, and spaced from each other, each of the trenches penetrating a portion of the via layer and the pixel-defining layer, and
wherein aspect ratios of the trenches are greater than 4.

21. The electronic device of claim 20, wherein the trenches have a tapered shape having a width that increases in a thickness direction.

22. The electronic device of claim 21, wherein a width of a top surface of each of the trenches is 80 nm to 130 nm, thicknesses of the trenches are about 600 nm or more, and taper angles of the trenches are about 85 degrees or more and less than about 90 degrees.

23. The electronic device of claim 20, wherein the pixel-defining layer comprises a triple-layered structure.

24. The electronic device of claim 23, wherein the triple-layered structure of the pixel-defining layer comprises:
a first layer comprising silicon oxide;
a second layer on the first layer, and comprising silicon nitride; and
a third layer on the second layer, and comprising silicon oxide.

25. The electronic device of claim 24, wherein the second layer and the third layer form an undercut structure by the trenches.

26. A wearable electronic device comprising,
a first display device configured to provide an image to a user's right eye; and
a second display device configured to provide an image to the user's left eye,
wherein at least one of the first display device and the second display device comprises:
a via layer on a pixel circuit layer;
anodes spaced from each other on the via layer;
a pixel-defining layer on the via layer and on edges of the anodes; and
trenches corresponding to the anodes, respectively, and spaced from each other, each of the trenches penetrating a portion of the via layer and the pixel-defining layer,
wherein aspect ratios of the trenches are greater than 4, and
wherein the wearable electronic device comprises at least one of a head mounted display (HMD) device, a virtual reality (VR) device, a mixed reality (MR) device, and an augmented reality (AR) device.
